(19) United States
(12) Patent Application Publication
(10) Pub. No.: US 2018/0136285 A1
(43) Pub. Date: May 17, 2018

(54) METHOD AND APPARATUS FOR ESTIMATING STATE OF BATTERY

(71) Applicant: SAMSUNG ELECTRONICS CO., LTD., Suwon-si (KR)

(72) Inventors: Kaeweon YOU, Hwaseong-si (KR); SangDo PARK, Seoul (KR)

(73) Assignee: SAMSUNG ELECTRONICS CO., LTD., Suwon-si (KR)

(21) Appl. No.: 15/491,519

(22) Filed: Apr. 19, 2017

(30) Foreign Application Priority Data
Nov. 16, 2016 (KR) 10-2016-0152727

(51) Int. Cl. G01R 31/36; H02J 7/00; B60L 11/18

(52) U.S. Cl. CPC G01R 31/3651; B60L 11/1864; B60L 11/1861; H02J 7/0021

(57) ABSTRACT

A method of estimating a state of a battery, the method includes actuating a controller to transformatively capture sensor data from a battery unit corresponding to an event associated with the battery unit; determine a state estimation model corresponding to the event among a plurality of state estimation models; input the transformed sensor data to the determined state estimation model; and estimate a state of the battery unit based on output information of the determined state estimation model.

### CROSS-REFERENCE TO RELATED APPLICATIONS

This application claims the benefit under 35 USC § 119(a) of Korean Patent Application No. 10-2016-0152727 filed on Nov. 16, 2016 in the Korean Intellectual Property Office, the entire disclosure of which is incorporated herein by reference for all purposes.

### BACKGROUND

### 1. Field

The following description relates to a method and apparatus for estimating a state of a battery.

### 2. Description of Related Art

Environmental and an energy conservation issues have become increasingly important and electric vehicles are in the spotlight as a future transportation device addressed to both issues. The electric vehicle uses, as a main power source, a battery in which a plurality of secondary cells capable of charging and discharging are configured into one or more packs. Thus, advantages, such as no exhaust gas, drilling, and reduced noise pollution, may be achieved.

In the electric vehicle, the battery serves to replace an engine and a fuel tank of a gasoline, diesel, ethanol, or other internal combustion-based vehicle. Accordingly, a state of the battery needs to be reliably verified to practically use the electric vehicle. According to an increasing use of the battery serving as a secondary cell, a lifespan of the battery significantly decreases. A reduction in the lifespan of the battery may lead to failures in securing the initial capacity of the battery and to gradually degrading the initial capacity of the battery. If the capacity of the battery continuously decreases, an output, an operation time, and safety desired by a driver may not be suitably provided. In this situation, the battery needs to be replaced. To determine a timing at which the battery is to be replaced, it is important to reliably determine a state of the battery and effectively forecast or predict its degradation.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

According to one aspect, a method of estimating a state of a battery includes actuating a controller to transformatively capture sensor data from a battery unit corresponding to an event associated with the battery unit; determining a state estimation model corresponding to the event among a plurality of state estimation models; inputting the transformed sensor data to the determined state estimation model; and estimating a state of the battery unit based on output information of the determined state estimation model.

The transformatively capturing may include extracting data from the sensor data based on a first time interval in response to the event being a discharging event associated with the battery unit; converting the extracted data to frequency domain data; filtering the frequency domain data; and converting the filtered frequency domain data to time domain data.

The transformatively capturing may further include deleting data included in a length over a predetermined reference in response to a length of the time domain data exceeding the predetermined reference.

The method may further include acquiring a parameter of a state estimation model corresponding to the discharging event; and applying the parameter to the state estimation model corresponding to the discharging event.

The transformatively capturing may include extracting data from the sensor data based on a second time interval in response to the event being a charging event associated with the battery unit.

The method may further include acquiring a parameter of a state estimation model corresponding to the charging event; and applying the parameter to the state estimation model corresponding to the charging event.

The plurality of state estimation models may include a first state estimation model exclusively configured to estimate the state of the battery unit during charging of the battery unit and a second state estimation model exclusively configured to estimate the state of the battery unit during discharging of the battery unit.

According to another general aspect, a method of training a battery state estimation model, includes classifying sensor data of a battery unit of an event associated with the battery unit; actuating a controller to transformatively process the sensor data based on the classified sensor data; inputting the processed sensor data to a state estimation model corresponding to the event; and training the state estimation model corresponding to the event in response to the input.

The transformative processing may include extracting data from the classified sensor data based on a first time interval in response to the event being a discharging event associated with the battery unit; converting the extracted data to frequency domain data; filtering the frequency domain data; and converting the filtered frequency domain data to time domain data.

The transformative processing may further include deleting data included in a length over a predetermined reference in response to a length of the time domain data exceeding the predetermined reference.

The inputting may include inputting the time domain data to a state estimation model corresponding to the discharging event.

The transformative processing may include extracting data from the sensor data based on a second time interval in response to the event being a charging event associated with the battery unit.

The inputting may include inputting the extracted data to a state estimation model corresponding to the charging event.

According to another general aspect, an apparatus for estimating a state of a battery includes: a communicator configured to receive sensor data of a battery unit; and a controller operably coupled to the communicator, the controller configured: to perform transformative processing corresponding to an event associated with the battery unit on sensor data of the battery unit, to determine a state estimation model corresponding to the event among a plurality of state estimation models, to input the processed sensor data to the determined state estimation model, and to estimate a state of the battery unit based on output information of the determined state estimation model.

The controller may be further configured: to extract data from the sensor data based on a first time interval in response to the event being a discharging event associated with the battery unit, to convert the extracted data to frequency domain data, to filter the frequency domain data, and to convert the filtered frequency domain data to time domain data.

The controller may be further configured to delete data included in a length over a predetermined reference in response to a length of the time domain data exceeding the predetermined reference.

The controller may be further configured to acquire a parameter of a state estimation model corresponding to the discharging event, and to apply the parameter to the state estimation model corresponding to the discharging event.

The controller may be further configured to extract data from the sensor data based on a second time interval in response to the event being a charging event associated with the battery unit.

The controller may be further configured to acquire a parameter of a state estimation model corresponding to the charging event, and to apply the parameter to the state estimation model corresponding to the charging event.

The plurality of state estimation models may include a first state estimation model exclusively configured to estimate the state of the battery unit during charging of the battery unit and a second state estimation model exclusively configured to estimate the state of the battery unit during discharging of the battery unit.

Other features and aspects will be apparent from the following detailed description, the drawings, and the claims.

### BRIEF DESCRIPTION OF THE DRAWINGS

FIG. 1 is a flowchart illustrating an example of a method of training a state estimation model.

FIG. 2 is a flowchart illustrating an example of a method of estimating a state of a battery.

FIG. 3 illustrates an example of sensing data of a battery unit.

FIG. 4 is a block diagram illustrating an example of a training apparatus for training a state estimation model.

FIG. 5 is a block diagram illustrating an example of a battery state estimation apparatus.

FIG. 6 is a block diagram illustrating an example of a battery system.

FIGS. 7 and 8 illustrate examples of a device that includes a battery system.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art after gaining a thorough understanding of the disclosure of this application. For example, the sequences of operations described herein are merely examples, and are not limited to those set forth herein, but may be changed as will be apparent to one of ordinary skill in the art from their knowledge gleaned of this disclosure, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after gaining an understanding of the disclosure of this application.

The following structural or functional descriptions are exemplary to merely describe the examples, and the scope of the examples is not limited to the descriptions provided in the present specification. Various changes and modifications can be made thereto by those of ordinary skill in the art.

Although terms of “first” or “second” are used to explain various components, the components are not limited to the terms. These terms should be used only to distinguish one component from another component. For example, a “first” component may be referred to as a “second” component, or similarly, and the “second” component may be referred to as the “first” component within the scope of the right according to the concept of the present disclosure.

It will be understood that when a component is referred to as being “connected to” another component, the component is directly connected or coupled to the other component or intervening components may be present.

As used herein, the singular forms are intended to include the plural forms as well, unless the context clearly indicates otherwise. It should be further understood that the terms “comprises” and/or “comprising,” when used in this specification, specify the presence of stated features, integers, steps, operations, elements, components or a combination thereof, but do not preclude the presence or addition of one or more other features, integers, steps, operations, elements, components, and/or groups thereof.

Unless otherwise defined herein, all terms used herein including technical or scientific terms have the same meanings as those generally understood by one of ordinary skill in the art. Terms defined in dictionaries generally used should be construed to have meanings matching with contextual meanings in the related art and are not to be construed as an ideal or excessively formal meaning unless otherwise defined herein.

Hereinafter, examples will be described in detail with reference to the accompanying drawings, and like reference numerals in the drawings refer to like elements throughout. When it is determined that detailed description related to the known art may make the example embodiments unnecessarily ambiguous, the detailed description is omitted.

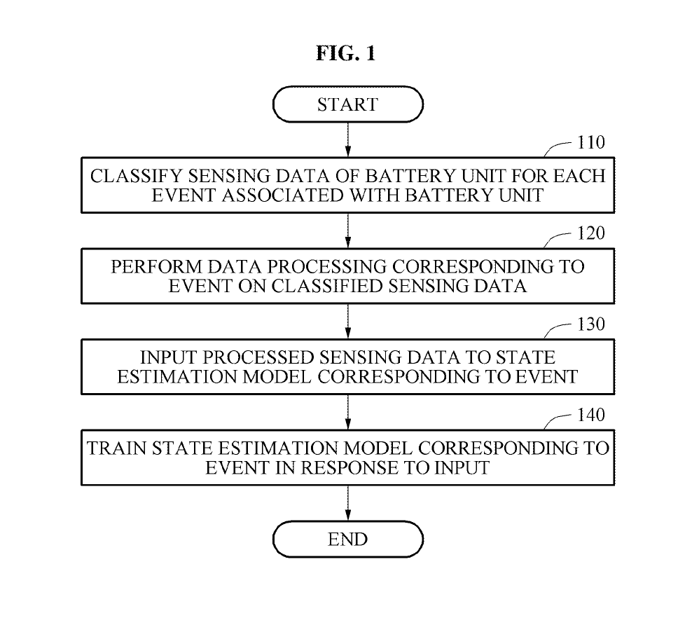

FIG. 1 illustrates an example of a method of training a state estimation model.

The state estimation model training method of FIG. 1 may be performed at a training apparatus.

in FIG. 1, the training apparatus acquires sensor or sensing data, such as operational parameters or characteristics of the battery unit or systems monitoring or powered by the battery unit, generated in response to an operation, for example, charging and discharging, of a battery unit. The battery unit may be, for example, a battery cell, a battery module, and/or a battery pack. Sensing data may include, for example, either one or combinations of two or more of voltage data, current data, temperature data, and impedance data of the battery unit.

Referring to FIG. 1, in operation 110, the training apparatus classifies sensing data of a battery unit for each event associated with the battery unit. The event may be, for example, a charging event, an error, warning, or a discharging event, and the training apparatus, according to one or more embodiments classifies the sensing data of the battery unit for each of the charging event and the discharging event. That is, the training apparatus classifies the sensing data into: (1) sensing data (hereinafter, charging data) of a charging section and (2) sensing data (hereinafter, discharging data) of a discharging section.

The training apparatus classifies sensing data into charging data and discharging data based on a charging ON signal and a charging OFF signal.

A frequency characteristic of charging data and a frequency characteristic of discharging data may differ from each other. The battery unit may be charged at constant current and constant voltage, according to embodiment. Thus, sensing data during charging, that is, charging data may not generally include a noise component that varies irregularly at a high frequency. Accordingly, charging data may be identified as a period having a primarily low frequency characteristic. In the case of discharging, sensing data during discharging, that is, discharging data may be identified as a period including a noise component that varies irregularly at a high frequency due to an operation environment, for example, a driving environment of an electric vehicle. Accordingly, discharging data may generally be characterized as having a high frequency characteristic. That is, discharging data may be discerned as that having a relatively large number of high frequency components compared to charging data.

As described above, a frequency characteristic of charging data and a frequency characteristic of discharging data may be identified as differing from each other. Thus, the training apparatus, according to one or more embodiments, processes charging data and discharging data using different procedures and employing different indicia based on a frequency characteristic. In operation 120, the training apparatus performs data processing to intelligently or transformatively capture sensor data corresponding to the event on the classified sensing data. In other words, according to one or more embodiments, sensor data is selectively and intelligently captured and transformed through several conversion, paring, and/or trimming, operations to arrive at highly indicative data about the battery unit. The training apparatus is configured to perform data processing corresponding to a charging event on charging data and to perform data processing corresponding to a discharging event on discharging data.

In the case of discharging data, the training apparatus, according to one or more embodiments, divides the discharging data based on a first time interval. In an example in which the first time interval is 1 Hz, the training apparatus extracts data from the discharging data approximately once per second. If a time length of discharging data includes 100 seconds, the training apparatus extracts data from the discharging data, in this example, once per second and acquires 100 pieces of data from the discharging data.

As described above, discharging data may be identified as having a high frequency component and data extracted from the discharging data may also have a high frequency component. The training apparatus, in some embodiments, performs filtering to remove the high frequency component. The training apparatus converts the extracted data to frequency domain data. For example, the training apparatus may convert the extracted data to the frequency domain data by applying a Fourier transform (FT) or Fast Fourier Transform (FFT) to the extracted data. The training apparatus filters the frequency domain data. The training apparatus inputs the frequency domain data to a high frequency filter to remove the high frequency component, in one or more embodiments. For example, the training apparatus removes approximately a top 80% of high frequency components through filtering. The training apparatus converts the filtered frequency domain data to time domain data. For example, the training apparatus converts the filtered frequency domain data to the time domain data by applying an inverse Fourier transform (IFT) to the filtered frequency domain data.

If a length of time domain data exceeds a predetermined reference, the training apparatus may perform a delete process. The predetermined reference may be adaptively established based on an amount of available storage memory, cache memory, a processing time, a heuristic approach to the battery state estimation model, or other considerations as would be apparent to one of skill in the art after gaining a thorough understanding of the disclosure of the subject application. The training apparatus may delete data included in a length over the predetermined reference. The training apparatus may perform the delete process to reduce a size of data to be input to a battery state estimation model. The deletion may be a selective paring of data based on relevance or other such factors. In the above example, FT, filtering, and IFT are performed on e.g. 100 pieces of data extracted from the discharging data. Here, the training apparatus verifies whether 100 corresponding to a number of pieces of extracted data exceeds the predetermined reference, for example, 80. Based on the verification result, the training apparatus deletes a portion of extracted data so that the number of pieces of extracted satisfies the predetermined reference.

Data processing performed on discharging data is described above. Hereinafter, data processing performed on charging data is described.

In the case of charging data, the training apparatus divides the charging data based on a second time interval. In an example in which the second time interval is 1/60 Hz, the training apparatus extracts data from the charging data once per 60 seconds. If a time length of charging data includes 6000 seconds, the training apparatus extracts data from the charging data once per 60 seconds and thereby acquires 100 pieces of data from the charging data.

In operation 130, the training apparatus inputs the processed sensing data to a state estimation model corresponding to the event. The training apparatus inputs the processed discharging data to a state estimation model corresponding to the discharging event. The training apparatus inputs the processed charging data to a state estimation model corresponding to the charging event.

In operation 140, the training apparatus trains the state estimation model corresponding to the event.

The training apparatus trains the state estimation model corresponding to the discharging event and the state estimation model corresponding to the charging event. If target state information is given, the training apparatus, according to one or more embodiments, trains a parameter of the state estimation model corresponding to the discharging event so that the state estimation model corresponding to the discharging event may output target state information. Also, the training apparatus trains a parameter of the state estimation model corresponding to the charging event so that the state estimation model corresponding to the charging event may output target state information.

Each of the state estimation models corresponding to the charging event and the state estimation model corresponding to the discharging event may include a black-box function where the state estimation model attempts to learn and characterize how the black-box function operates based on inputs provided and outputs generated based on those inputs. The training apparatus may train a parameter of the black-box function based on an input and an output given for the black-box function. As the state estimation model corresponding to each of the charging event and the discharging event, a neural network model, a recurrent neural network (RNN) model, a long short term memory (LSTM) RNN model, a support vector machine (SVM) model, a Gaussian process regression (GPR) model, and the like, may be used. However, they are provided as an example only and examples of the state estimation model are not limited thereto.

In the case of using the neural network model, such as the LSTM RNN model, as the state estimation model corresponding to each of the charging event and the discharging event, the parameter may include a connection pattern between artificial neurons, a weight, or other suitable configurations. In the case of using the SVM model as the state estimation model corresponding to each of the charging event and the discharging event, the parameter includes, for example, a penalty parameter. Also, in the case of using the GPR model as the state estimation model corresponding to each of the charging event and the discharging event, the parameter includes, for example, a hyper-parameter.

In one example, a type of the state estimation model corresponding to the charging event differs from a type of the state estimation model corresponding to the discharging model.

The training apparatus distinguishes the charging event and the discharging event from each other and trains the state estimation models corresponding to the respective charging event and discharging event. The training apparatus stores, in a memory, the parameters of the state estimation models corresponding to the charging event and the discharging event of which training is completed. The parameters of the state estimation models are then used to estimate a state of a battery.

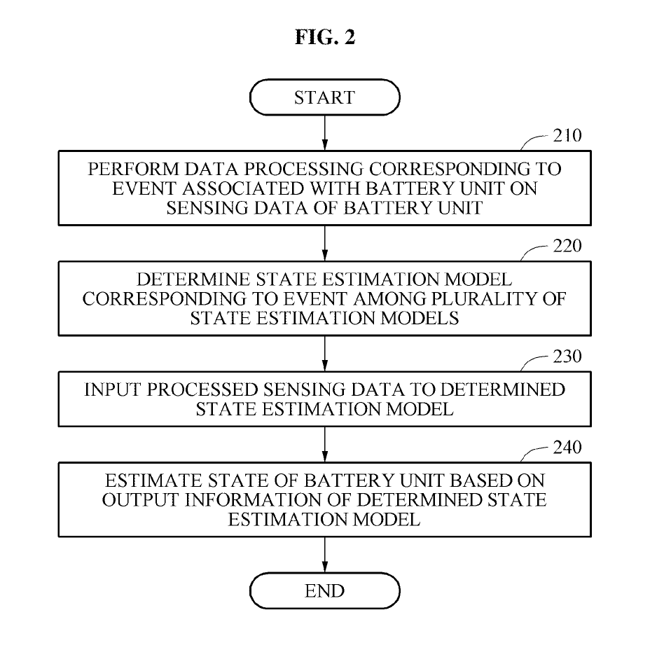

FIG. 2 illustrates an example of a method of estimating a state of a battery.

The battery state estimation method of FIG. 2 is performed at a battery state estimation apparatus.

Referring to FIG. 2, in operation 210, the battery state estimation apparatus performs data processing corresponding to an event associated with a battery unit on a sensing data of the battery unit. The battery unit may be charged or discharged. That is, a charging event or a discharging event may occur in the battery unit.

In response to discharging of the battery unit, the battery state estimation apparatus collects sensing data of the battery unit being discharged. The battery state estimation apparatus performs data processing corresponding to the discharging event on the sensing data. Hereinafter, data processing corresponding to the discharging event is described.

In one example, the battery state estimation apparatus divides sensing data based on a first time interval. In an example in which the first time interval is 1 Hz, the battery state estimation apparatus extracts data once per second. If a time length of sensing data includes 100 seconds, the battery state estimation apparatus may extract data from the sensing data once per second and acquire 100 pieces of data from the sensing data.

The battery state estimation apparatus extracts data from the sensing data based on a time interval less than the first time interval. In this case, a data computation amount may increase and an estimation accuracy may be enhanced.

The battery state estimation apparatus may extract data from the sensing data based on a time interval greater than the first time interval. In this case, the entire trend of a sensing data pattern may not be maintained and the estimation accuracy may be degraded.

The first time interval may be set to a substantially optimal value based on the data computation amount and the estimation accuracy desired.

The battery state estimation apparatus converts the extracted data to frequency domain data. For example, the battery state estimation apparatus converts the extracted data to the frequency domain data by applying a Fourier transform (FT) to the extracted data. The battery state estimation apparatus filters the frequency domain data. The battery state estimation apparatus, for example, inputs the frequency domain data to a high frequency filter to remove the high frequency component. For example, the battery state estimation apparatus removes a top 80% of high frequency components through filtering. The battery state estimation apparatus, according to one or more embodiments, converts the filtered frequency domain data to time domain data. For example, the battery state estimation apparatus converts the filtered frequency domain data to the time domain data by applying an inverse Fourier transform (IFT) to the filtered frequency domain data.

The battery state estimation apparatus verifies whether a length of time domain data exceeds a predetermined reference. Based on the verification result, the battery state estimation apparatus performs a delete process. The battery state estimation apparatus may delete data included in a length over the predetermined reference. That is, if a number of pieces of time domain data exceeds the predetermined reference, the battery state estimation apparatus deletes time domain data exceeding the predetermined reference. Accordingly, a size of data to be input to the state estimation model is reduced.

Data processing corresponding to the discharging event is described above. Hereinafter, data processing corresponding to the charging event is described.

In response to charging of the battery unit, the battery state estimation apparatus collects sensing data of the battery unit being charged. The battery state estimation apparatus performs data processing corresponding to the charging event on the sensing data. The battery state estimation apparatus, according to one or more embodiments, divides the sensing data based on a second time interval. In an example in which the second time interval is 1/60 Hz, the battery state estimation apparatus extracts data from the sensing data once per 60 seconds. If a time length of sensing data includes 6000 seconds, the battery state estimation apparatus extracts data from the charging data once per 60 seconds and, accordingly, acquires 100 pieces of data from the sensing data. Data processing corresponding to the charging event is described.

In operation 220, the battery state estimation apparatus determines a state estimation model corresponding to the event among a plurality of state estimation models. In response to an occurrence of the discharging event, the battery state estimation apparatus selects a state estimation model corresponding to the discharging event from among the plurality of state estimation models. In response to an occurrence of the charging event, the battery state estimation apparatus selects a state estimation model corresponding to the charging event from among the plurality of state estimation models.

In operation 230, the battery state estimation apparatus inputs the processed sensing data to the determined state estimation model.

In response to an occurrence of the discharging event, the battery state estimation apparatus inputs sensing data on which data processing corresponding to the discharging event is performed to the state estimation model corresponding to the discharging event. The battery state estimation apparatus, according to an embodiment, acquires a parameter of the state estimation model corresponding to the discharging event. For example, the parameter is stored in a memory, and the battery state estimation apparatus acquires the parameter by referring to the memory. The battery state estimation apparatus applies the acquired parameter to the state estimation model corresponding to the discharging event.

In response to the occurrence of the charging event, the battery state estimation apparatus inputs sensing data (on which data processing corresponding to the charging event is performed) to the state estimation model corresponding to the charging event. The battery state estimation apparatus acquires a parameter of the state estimation model corresponding to the charging event. For example, the parameter is stored in a memory, and the battery state estimation apparatus acquires the parameter by referring to the memory. The battery state estimation apparatus applies the acquired parameter to the state estimation model corresponding to the charging event.

The parameter of the state estimation model corresponding to the charging event and the parameter of the state estimation model corresponding to the discharging event may be trained in advance. For example, the parameters are trained by the training apparatus of FIG. 1.

In operation 240, the battery state estimation apparatus estimates a state of the battery unit based on output information of the determined state estimation model. The state of the battery unit may include, for example any one or any combination of two or more of a lifespan state, such as state of health (SOH), a remaining capacity state, state of charge (SOC), etc. However, the state of the battery unit is not limited thereto.

According to an increase in a number of charging and discharging cycles, the battery may be aged and a lifespan of the battery may be reduced. The lifespan of the battery represents a period in which the battery normally supplies power to an external load. If the current capacity of the battery reaches a threshold, for example, 80%, or is less than or equal to the threshold, the battery may not meet the requirements of an application and should be replaced. To determine a timing at which the battery is to be replaced, it is important to accurately estimate the lifespan of the battery.

In one example, the battery state estimation apparatus estimates a state corresponding to each of the charging event and the discharging event. In one example, the state estimation model may be dualized to a state estimation model suitable for a charging situation and to a state estimation model suitable for a discharging situation and the estimation accuracy for the state of the battery unit may be enhanced. Also, the battery state estimation apparatus, according to one or more embodiments, estimates the state of the battery unit to be suitable for an operation situation of the battery unit and estimates the state of the battery unit for each charging and discharging characteristic. Accordingly, the state of the battery is significantly more accurately estimated.

The battery state estimation apparatus estimates the state of the battery unit by recognizing one or more patterns of sensing data and thus, estimates the state of the battery unit in real time. The battery state estimation apparatus estimates the state of the battery unit in the case of a complete charging and discharging situation and a partial charging and discharging situation.

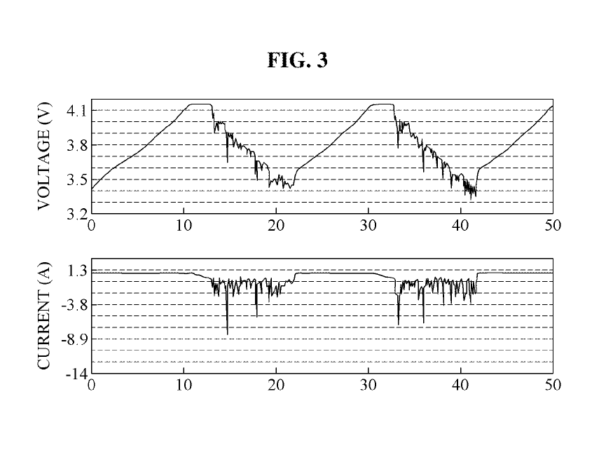

FIG. 3 illustrates an example of sensing data of a battery unit.

Graphs of FIG. 3 show sensing data of a battery unit having gone through multiple charging and discharging cycles.

Referring to FIG. 3, during charging of the battery unit, voltage of the battery unit constantly increases and current of the battery unit is nearly constant. Accordingly, sensing data during charging is identified as having a low frequency characteristic. During discharging of the battery unit, the voltage and the current of the voltage unit generally include a noise component that varies irregularly at a high frequency. Accordingly, sensing data during discharging is identified as having a high frequency component, such as noise, compared to sensing data during charging.

It is assumed that the training apparatus has acquired sensing data of FIG. 3. The training apparatus classifies the sensing data into sensing data during discharging, that is, discharging data, and sensing data during charging, that is, charging data. As described above, the training apparatus extracts partial data from the discharging data based on a first time interval, and performs FT, for example, fast Fourier transform (FFT) or discrete Fourier transform (DFT), high frequency filtering, IFT, for example, inverse FFT (IFFT) or IDFT, and a delete process. As another example, the training apparatus extracts partial data from the discharging data by applying FT, high frequency filtering, and IFT to the discharging data, and performs the delete process.

As described above, the training apparatus extracts partial data from charging data based on a second time interval. As another example, the training apparatus extracts data based on the first time interval less than the second time interval. In this case, a number of pieces of data to be extracted increase and the complexity of a state estimation model corresponding to charging data increase and a computation amount increases.

In one example, a time interval applied to discharging data is less than a time interval applied to charging data. In the above example, the first time interval may be less than the second time interval to maintain the overall trend of a discharging data pattern. In other words, if data is extracted from discharging data once per 60 seconds, a time interval between data to be extracted increases and the overall trend of the discharging data pattern may not be readily identified. For example, if data is extracted from discharging data once per second, a time interval between data to be extracted decreases and the overall trend of the discharging data pattern may be maintained.

In response to completion of training, each of a parameter of the state estimation model corresponding to the charging event and a parameter of the state estimation model corresponding to the discharging event are acquired.

The battery state estimation apparatus collects sensing data during discharging of the battery unit, processes the sensing data, and inputs the processed sensing data to the state estimation model corresponding to the discharging event. Likewise, the battery state estimation apparatus collects sensing data during charging of the battery unit, processes the sensing data, and inputs the processed sensing data to the state estimation model corresponding to the charging event.

Because the battery state estimation apparatus estimates the state of the battery through an exclusive model used in response to the occurrence of the charging event and an exclusive model used in response to the occurrence of the discharging event, the estimation accuracy may be enhanced.

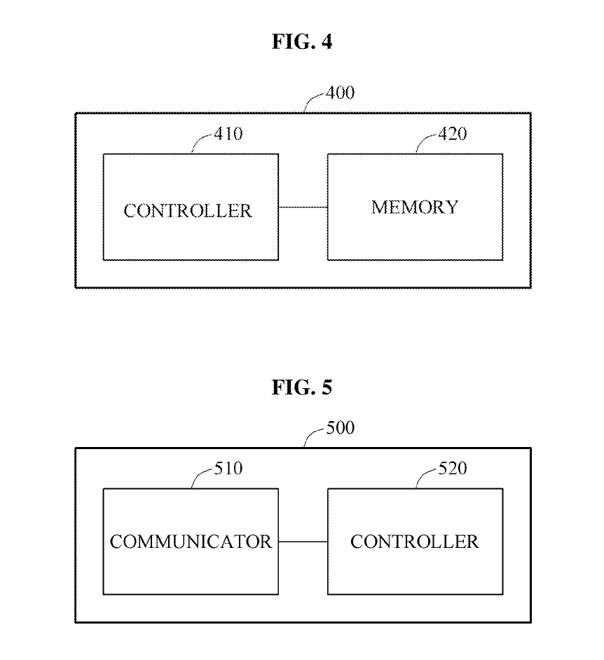

FIG. 4 illustrates an example of a training apparatus for training a state estimation model.

Referring to FIG. 4, a training apparatus 400 includes a controller 410 operably coupled to a memory 420. The training apparatus 400 performs the state estimation model training method of FIG. 1 when coupled to a battery unit.

The controller 410 classifies sensing data of a battery unit for each event associated with the battery unit. For example, the controller 410 classifies the sensing data of FIG. 3 into charging data and discharging data.

The controller 410 performs data processing corresponding to an event on the classified sensing data. For example, the controller 410 performs data processing corresponding to a discharging event on the discharging data, and performs data processing corresponding to a charging event on the charging data.

The controller 410 inputs the processed sensing data to a state estimation model corresponding to the event. For example, the controller 410 inputs the processed discharging data to a state estimation model corresponding to the discharging event, and inputs the processed charging data to a state estimation model corresponding to the charging event.

The controller 410 trains the state estimation model corresponding to the event. For example, the controller 410 trains each of the state estimation model corresponding to the charging event and the state estimation model corresponding to the discharging event. The controller 410 inputs first training data, for example, the processed discharging data, to the state estimation model corresponding to the discharging event. Also, the controller 410 inputs second training data, for example, the processed charging data, to the state estimation model corresponding to the charging event. The controller 410 trains the state estimation model to decrease a difference between a result value output from each state estimation model and an actual measurement value, or a target result value, of the battery unit. Through a training process, a parameter of the state estimation model is optimized.

In the case of using a neural network model as the state estimation model, the controller 410 trains the state estimation model using, for example, an error back-progression learning scheme and the like. The error back-progression learning scheme estimates an error through forward computation for given training data, propagates the estimated error starting from an output layer of the neural network model back to a hidden layer and an input layer, and updates a connection weight between artificial neurons to reduce the error. Accordingly, the parameter, for example, the connection weight, is optimized.

The memory 420 stores the parameter of the state estimation model of which training is completed.

The description made above with reference to FIGS. 1 through 3 may be applicable to the example of FIG. 4 and a duplicate detailed description thereof is omitted for clarity and conciseness.

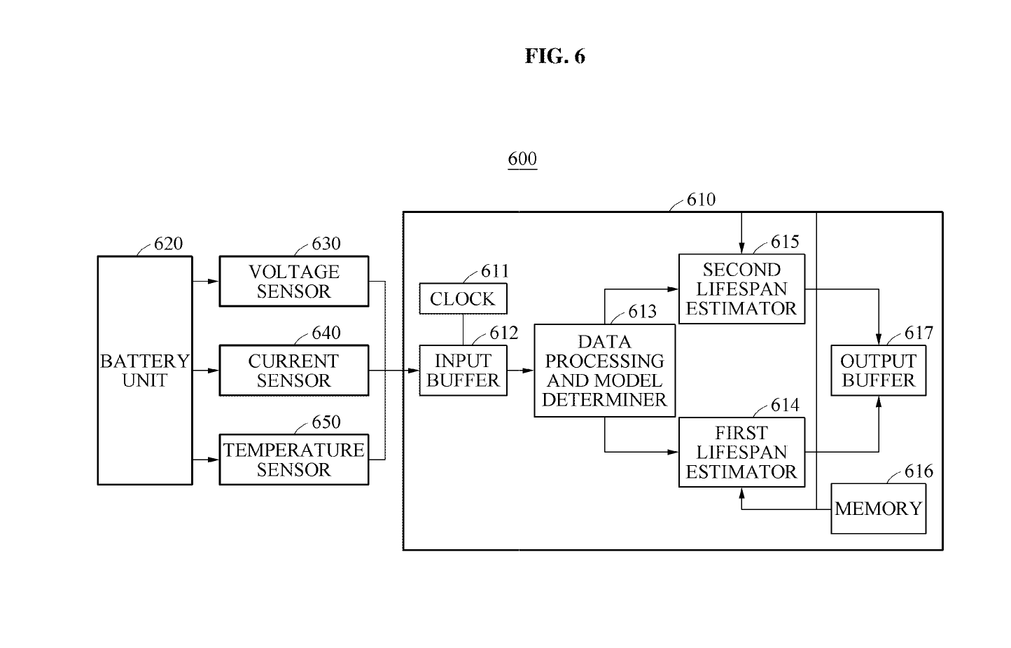

FIG. 5 illustrates an example of a battery state estimation apparatus.

Referring to FIG. 5, a battery state estimation apparatus 500, according to an embodiment, includes a communicator 510 operably coupled to a controller 520.

The communicator 510 receives sensing data of the battery unit.

The controller 520 performs data processing corresponding to an event associated with the battery unit on the sensing data. For example, in response to an occurrence of a charging event in the battery unit, the controller 520 performs data processing corresponding to the charging event on sensing data during charging. In response to an occurrence of a discharging event in the battery unit, the controller 520 performs data processing corresponding to the discharging event on sensing data during discharging.

The controller 520 determines a state estimation model corresponding to the event among a plurality of state estimation models.

The controller 520 inputs the processed sensing data to the determined state estimation model.

The controller 520 estimates the state of the battery unit based on output information of the determined state estimation model.

The description made above with reference to FIGS. 1 through 4 may be applicable to the example of FIG. 5 and a duplicative detailed description is omitted for clarity and conciseness.

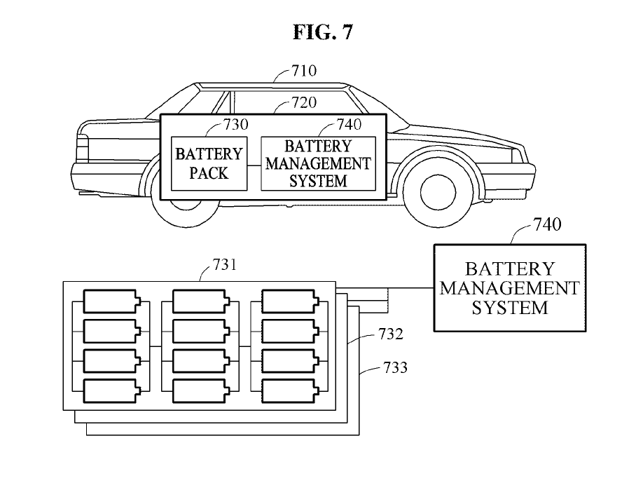

FIG. 6 illustrates an example of a battery system.

Referring to FIG. 6, a battery system 600 includes a battery state estimation apparatus 610, a battery unit 620, and a plurality of sensors, for example, a voltage sensor 630, a current sensor 640, and a temperature sensor 650.

Although FIG. 6 illustrates the plurality of sensors, for example, the voltage sensor 630, the current sensor 640, and the temperature sensor 650, outside the battery state estimation apparatus 610, the plurality of sensors may be included in the battery state estimation apparatus 610 depending on examples.

The battery unit 620 supplies power to a device, a machine, and the like, to which the battery unit 620 is mounted. The battery unit 620 is, for example, a battery cell, a battery module, or a battery pack.

The voltage sensor 630 acquires voltage data by sensing a voltage of the battery unit 620, and the current sensor 640 acquires current data by sensing a current of the battery unit 620. The temperature sensor 650 acquires temperature data by sensing a temperature of the battery unit 620.

The battery state estimation unit 610 includes a clock 611, an input buffer 612, a data processing and model determiner 613, a first lifespan estimator 614, a second lifespan estimator 615, a memory 616, and an output buffer 617.

One of the data processing and model determiner 613, the first lifespan estimator 614, and the second lifespan estimator 615, or a combination thereof may be configured by at least one processing device.

The input buffer 612 stores data such as sensing data received from the voltage sensor 630, the current sensor 640, and the temperature sensor 650. The clock 611 maintains a current time and provides time information to the input buffer 612. The input buffer 612 records a time at which sensing data is received based on time information received from the clock 611.

The data processing and model determiner 613 processes the sensing data and determines a state estimation model. Also, the data processing and model determiner 613 assigns the processed sensing data to one of the first lifespan estimator 614 and the second lifespan estimator 615. The data processing and model determiner 613 may operate as an assignor. The first lifespan estimator 614 includes a state estimation model corresponding to a charging event. The first lifespan estimator 614, according to one or more embodiments, is a charging-dedicated lifespan estimator. The second lifespan estimator 615 includes a state estimation model corresponding to a discharging event. The second lifespan estimator 615 is a discharging-dedicated lifespan estimator.

In response to sensing data being voltage, current, temperature, etc., being sensed during charging of the battery unit 620, the data processing and model determiner 613 performs data processing corresponding to the charging event on the sensing data. The data processing and model determiner 613 assigns the processed sensing data to the first lifespan estimator 614 to estimate a state of the battery unit 620. The data processing and model determiner 613 selects the state estimation model corresponding to the charging event and inputs the processed sensing data to the first lifespan estimator 614.

In response to sensing data being voltage, current, temperature, etc., being sensed during discharging of the battery unit 620, the data processing and model determiner 613 performs data processing corresponding to the discharging event on the sensing data. The data processing and model determiner 613 assigns the processed sensing data to the second lifespan estimator 615 to estimate a state of the battery unit 620. The data processing and model determiner 613 selects the state estimation model corresponding to the discharging event and inputs the processed sensing data to the second lifespan estimator 615.

The first lifespan estimator 614 acquires a parameter of the state estimation model corresponding to the charging event from the memory 616 during charging of the battery unit 620, and applies the acquired parameter to the state estimation model corresponding to the charging event. During charging of the battery unit 620, the second lifespan estimator 615 may not be used. The first lifespan estimator 614 may be exclusively used to estimate the state of the battery unit 620 being charged.

The second lifespan estimator 615 acquires a parameter of the state estimation model corresponding to the discharging event from the memory 616 during discharging of the battery unit 620, and applies the acquired parameter to the state estimation model corresponding to the discharging event. During discharging of the battery unit 620, the first lifespan estimator 614 may not be used. The second lifespan estimator 615, in one or more embodiments, is exclusively used to estimate the state of the battery unit 620 being discharged.

The first lifespan estimator 614 or the second lifespan estimator 615 store output information of the state estimation model in the output buffer 617. The output information is an estimate value about the state of the battery unit 620.

The battery state estimation apparatus 610 transmits information about the lifespan of the battery unit 620 to another apparatus or outputs the information through a visual, audible, or other type of interface device such as a display device.

The memory 616 stores the parameter of the trained state estimation model. The memory 616 includes, for example, a dynamic random access memory (DRAM), a static RAM (SRAM), a ferroelectrics RAM (FRAM), a flash memory, a hard disk drive (HDD), a solid state drive (SDD), and the like. However, the example of the memory 616 is not limited thereto.

The description made above with reference to FIGS. 1 through 5 may be applicable to the example of FIG. 6 and a detailed description is omitted for succinctness and clarity.

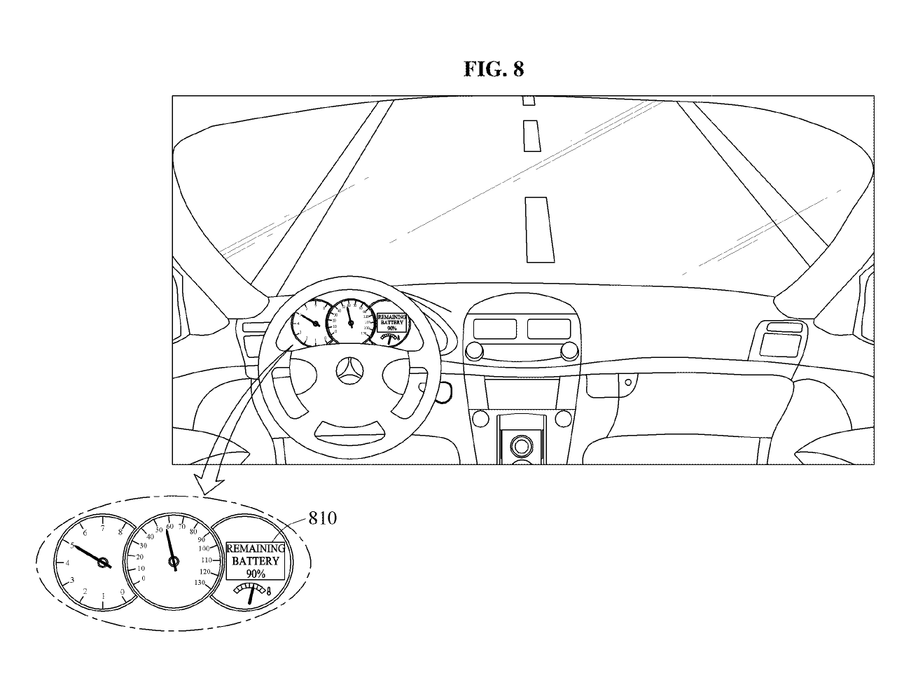

FIGS. 7 and 8 illustrate examples of a device that includes a battery system.

Referring to FIG. 7, a device 710 that includes a battery system 720 is a vehicle that uses a battery as a power source. The vehicle may be, for example, an electric vehicle or a hybrid vehicle. It is provided as an example only and the example of the device 710 is not limited thereto.

The battery system 720 includes a battery pack 730 and a battery management system 740.

The battery pack 730 includes a plurality of battery modules 731, 732, and 733. Each of the plurality of battery modules 731, 732, and 733 includes at least one battery cell.

The battery management system 740 may correspond to the aforementioned battery state estimation apparatus. In detail, the battery management system 740 collects one of cell data of a battery cell included in each of the plurality of battery modules 731, 732, and 733, module data of each of the plurality of battery modules 731, 732, and 733, and pack data of the battery pack 730, or a combination thereof. The cell data represents voltage data of a battery cell, etc., the module data represents voltage data, etc., of each of the plurality of battery modules 731, 732, and 733, and the pack data represents voltage data, etc., of the battery pack 730 and the like.

The battery management system 740 estimates a state of the battery pack 730 being charged. Also, the battery management system 740 estimates a state of the battery pack 730 being charged or discharged. State estimation is described above and a further description is omitted.

The battery management system 740, according to one or more embodiments, transmit the estimated state to a user terminal. The estimated state of the battery pack 730 is, for example, visually displayed on a display of the user terminal.

The description made above with reference to FIGS. 1 through 6 may be applicable to the example of FIG. 7 and a detailed description is omitted for conciseness and clarity.

Referring to FIG. 8, a battery state 810 is output on a dashboard. A battery management system estimates the state 810 even during driving of a device. The battery management system transmits state information to an electronic control unit (ECU), and the ECU may display the state 810 on the dashboard or other location near a charging port of the device 710. Also, the ECU may output the state 810 on another display within the device. Also, auditory feedback, such as a notification sound saying “the battery is running out”, as well as visual feedback may be output.

Examples of hardware components include controllers, sensors, generators, drivers, and any other electronic components known to one of ordinary skill in the art. In one example, the hardware components are implemented by one or more processors or computers. A processor or computer is implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices known to one of ordinary skill in the art that is capable of responding to and executing instructions in a defined manner to achieve a desired result. In one example, a processor or computer includes, or is connected to, one or more memories storing instructions or software that are executed by the processor or computer. Hardware components implemented by a processor or computer execute instructions or software, such as an operating system (OS) and one or more software applications that run on the OS, to perform the operations described herein. The hardware components also access, manipulate, process, create, and store data in response to execution of the instructions or software. For simplicity, the singular term “processor” or “computer” may be used in the description of the examples described herein, but in other examples multiple processors or computers are used, or a processor or computer includes multiple processing elements, or multiple types of processing elements, or both. In one example, a hardware component includes multiple processors, and in another example, a hardware component includes a processor and a controller. A hardware component has any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

Instructions or software to control a processor or computer to implement the hardware components and perform the methods as described above are written as computer programs, code segments, instructions or any combination thereof, for individually or collectively instructing or configuring the processor or computer to operate as a machine or special-purpose computer to perform the operations performed by the hardware components and the methods as described above. In one example, the instructions or software include machine code that is directly executed by the processor or computer, such as machine code produced by a compiler. In another example, the instructions or software include higher-level code that is executed by the processor or computer using an interpreter. Programmers of ordinary skill in the art, after gaining a thorough understanding of the subject disclosure in this application, can readily write the instructions or software based on the block diagrams and the flow charts illustrated in the drawings and the corresponding descriptions in the specification, which disclose algorithms for performing the operations performed by the hardware components and the methods as described above.

The instructions or software to control a processor or computer to implement the hardware components and perform the methods as described above, and any associated data, data files, and data structures, are recorded, stored, or fixed in or on one or more non-transitory computer-readable storage media. Examples of a non-transitory computer-readable storage medium include read-only memory (ROM), random-access memory (RAM), flash memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, magnetic tapes, floppy disks, magneto-optical data storage devices, optical data storage devices, hard disks, solid-state disks, and any device known to one of ordinary skill in the art that is capable of storing the instructions or software and any associated data, data files, and data structures in a non-transitory manner and providing the instructions or software and any associated data, data files, and data structures to a processor or computer so that the processor or computer can execute the instructions. In one example, the instructions or software and any associated data, data files, and data structures are distributed over network-coupled computer systems so that the instructions and software and any associated data, data files, and data structures are stored, accessed, and executed in a distributed fashion by the processor or computer.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A method of estimating a state of a battery, the method comprising:
actuating a controller to transformatively capture sensor data from a battery unit corresponding to an event associated with the battery unit;
determining a state estimation model corresponding to the event among a plurality of state estimation models;
inputting the transformed sensor data to the determined state estimation model; and
estimating a state of the battery unit based on output information of the determined state estimation model.

2. The method of claim 1, wherein the transformatively capturing comprises:
extracting data from the sensor data based on a first time interval in response to the event being a discharging event associated with the battery unit;
converting the extracted data to frequency domain data;
filtering the frequency domain data; and
converting the filtered frequency domain data to time domain data.

3. The method of claim 2, wherein the transformatively capturing further comprises:
deleting data included in a length over a predetermined reference in response to a length of the time domain data exceeding the predetermined reference.

4. The method of claim 2, further comprising:
acquiring a parameter of a state estimation model corresponding to the discharging event; and
applying the parameter to the state estimation model corresponding to the discharging event.

5. The method of claim 1, wherein the transformatively capturing comprises:
extracting data from the sensor data based on a second time interval in response to the event being a charging event associated with the battery unit.

6. The method of claim 5, further comprising:
acquiring a parameter of a state estimation model corresponding to the charging event; and
applying the parameter to the state estimation model corresponding to the charging event.

7. The method of claim 1, wherein the plurality of state estimation models comprise a first state estimation model exclusively configured to estimate the state of the battery unit during charging of the battery unit and a second state estimation model exclusively configured to estimate the state of the battery unit during discharging of the battery unit.

8. A method of training a battery state estimation model, the method comprising:
classifying sensor data of a battery unit of an event associated with the battery unit;
actuating a controller to transformatively process the sensor data based on the classified sensor data;
inputting the processed sensor data to a state estimation model corresponding to the event; and
training the state estimation model corresponding to the event in response to the input.

9. The method of claim 8, wherein the transformative processing comprises:
extracting data from the classified sensor data based on a first time interval in response to the event being a discharging event associated with the battery unit;
converting the extracted data to frequency domain data;
filtering the frequency domain data; and
converting the filtered frequency domain data to time domain data.

10. The method of claim 9, wherein the performing of the transformative processing further comprises:
deleting data included in a length over a predetermined reference in response to a length of the time domain data exceeding the predetermined reference.

11. The method of claim 9, wherein the inputting comprises inputting the time domain data to a state estimation model corresponding to the discharging event.

12. The method of claim 8, wherein the transformative processing comprises:
extracting data from the sensor data based on a second time interval in response to the event being a charging event associated with the battery unit.

13. The method of claim 12, wherein the inputting comprises:
inputting the extracted data to a state estimation model corresponding to the charging event.

14. An apparatus for estimating a state of a battery, the apparatus comprising:
a communicator configured to receive sensor data of a battery unit; and
a controller operably coupled to the communicator, the controller configured:
to perform transformative processing corresponding to an event associated with the battery unit on sensor data of the battery unit,
to determine a state estimation model corresponding to the event among a plurality of state estimation models,
to input the processed sensor data to the determined state estimation model, and
to estimate a state of the battery unit based on output information of the determined state estimation model.

15. The apparatus of claim 14, wherein the controller is further configured:
to extract data from the sensor data based on a first time interval in response to the event being a discharging event associated with the battery unit,
to convert the extracted data to frequency domain data,
to filter the frequency domain data, and
to convert the filtered frequency domain data to time domain data.

16. The apparatus of claim 15, wherein the controller is further configured to delete data included in a length over a predetermined reference in response to a length of the time domain data exceeding the predetermined reference.

17. The apparatus of claim 15, wherein the controller is further configured to acquire a parameter of a state estimation model corresponding to the discharging event, and to apply the parameter to the state estimation model corresponding to the discharging event.

18. The apparatus of claim 14, wherein the controller is further configured to extract data from the sensor data based on a second time interval in response to the event being a charging event associated with the battery unit.

19. The apparatus of claim 18, wherein the controller is further configured to acquire a parameter of a state estimation model corresponding to the charging event, and to apply the parameter to the state estimation model corresponding to the charging event.

20. The apparatus of claim 14, wherein the plurality of state estimation models comprise a first state estimation model exclusively configured to estimate the state of the battery unit during charging of the battery unit and a second state estimation model exclusively configured to estimate the state of the battery unit during discharging of the battery unit.
